(19) United States
(12) Patent Application Publication
(10) Pub. No.: US 2014/0124367 A1
(43) Pub. Date: May 8, 2014

(54) SAMPLE PREPARATION APPARATUS, SAMPLE PREPARATION METHOD, AND CHARGED PARTICLE BEAM APPARATUS USING THE SAME

(71) Applicants: Shuichi Takeuchi, Tokyo (JP); Hisayuki Takasu, Tokyo (JP); Asako Kaneko, Tokyo (JP)

(72) Inventors: Shuichi Takeuchi, Tokyo (JP); Hisayuki Takasu, Tokyo (JP); Asako Kaneko, Tokyo (JP)

(21) Appl. No.: 14/128,646

(22) PCT Filed: Apr. 25, 2012
(86) PCT No.: PCT/JP2012/002820

§ 371 Date: Dec. 23, 2013

(30) Foreign Application Priority Data
Jun. 30, 2011 (JP) 2011-145161

(51) Int. Cl. H01J 37/30; H01J 37/16; H01J 37/305

(52) U.S. Cl. CPC H01J 37/3005; H01J 37/3056; H01J 37/16
USPC 204/298.32; 204/298.31

(57) ABSTRACT

There is provided an apparatus as well as a method for polishing, observing, and additionally polishing a sample in a vacuum with a charged particle beam apparatus furnished with no other apparatus.

The charged particle beam apparatus has a vacuum chamber equipped with a liquid bath containing an ion liquid and a supersonic vibration means. With the ion liquid kept in contact with a polishing target area of the sample, supersonic vibration is propagated in the ion liquid to polish the sample.

Because the charged particle beam apparatus permits polishing, observation, and additional polishing of the sample in a vacuum without being furnished with any additional apparatus, throughput is improved and the effects of the atmosphere on the sample are prevented.

### TECHNICAL FIELD

The present invention relates to a sample preparation apparatus. More particularly, the invention relates to an apparatus and a method for efficiently preparing samples in a vacuum.

### BACKGROUND ART

Ultrasonic polishing is one way of polishing samples. Ultrasonic polishing is a method whereby a liquid mixture (working fluid) of abrasive particles and water is interposed between a sample and the tool, the latter being subjected to supersonic vibration to make the abrasive particles collide with the sample. This method offers the advantage of polishing the sample extensively over a short period of time.

Patent Document 1 cited below explains a technique which, in polishing sintered materials such as fine ceramics, involves thermally processing a sample and then getting the processed sample polished by a numerically controlled ultrasonic polishing machine that controls the position, pressure, etc., of the sample during polishing.

There also is a method whereby a liquid bath is given supersonic vibration to generate air bubbles that burst and release impact force to be used. Patent Document 2 cited below explains a technique that uses this energy to raise the internal pressure of a container containing a liquid in which a sample is dipped, thereby generating ultrasonic waves to polish the sample surface.

The polishing methods described above require transporting the sample in the atmosphere to another apparatus if the polished sample is to be observed and analyzed. At that time, the sample surface exposed to the atmosphere can be oxidized and contaminated with impurities.

One way of preventing the influence of the atmosphere on the sample is by using an ion liquid. Patent Document 3 cited below shows that an ion-milled sample is impregnated or coated with an ion liquid so that the entire sample is covered with the liquid for protection against exposure to the atmosphere during transportation therethrough. Patent Document 4 cited below shows that a sample is impregnated or coated with an ion liquid to prevent the moisture in the sample from evaporating even in a vacuum so that samples such as biological samples containing moisture in particular may be observed in their original shape without getting shrunk.

### PRIOR ART DOCUMENTS

### Patent Document

Patent Document 1: JP-1977-34727-A
Patent Document 2: JP-1990-30463-A
Patent Document 3: JP-2010-25656-A
Patent Document 4: WO2007/083756

### SUMMARY OF THE INVENTION

### Problem to be Solved by the Invention

Patent Document 1 and 2 show examples in which samples are polished using ultrasonic waves. However, they have no reference to the effects of oxidation and contamination on the polished sample following exposure to the atmosphere. Letting the polished area of the sample surface undergo such effects should make it difficult to observe or analyze the sample accurately.

Patent Document 3 and 4 also show examples in which, with an ion liquid in use, the sample surface is observed without exposure to the atmosphere. The ion liquid is a type of molten salt composed of cations and anions and is designed to have a significantly low melting point. The vapor pressure of the ion liquid is infinitely close to zero, and the ion liquid has the characteristic of maintaining its liquid state at room temperature, when heated, or in a vacuum. However, according to the techniques disclosed by Patent Documents 3 and 4, if the sample needs to be polished again (additionally) following observation because the previous treatment of the sample turned out to be insufficient, it is necessary to remove the sample from the observation apparatus and transport it in the atmosphere to the polishing apparatus. Where the sample is to be polished, observed, and analyzed in this manner using different apparatuses, the process of moving the sample therebetween needs to be repeated, which can be troublesome work.

There also exist methods of processing the sample in a vacuum such as the ion milling method disclosed by Patent Document 3. This method involves getting accelerated ions to collide with the sample surface, thereby flicking off atoms and molecules from the sample for polishing. Because it permits polishing while maintaining a vacuum state, the method can prevent the influence of the atmosphere and may also be implemented with an observation apparatus. However, this method is not practical because it has low polishing efficiency and takes a long time to polish a sample before the sample can be processed into a desired state.

Incidentally, if the type of ultrasonic polishing described in Patent Documents 1 and 2 were applied to a vacuum state, liquid components such as a liquid mixture of abrasive particles and water and a cleaning liquid would evaporate, making sample polishing difficult to achieve.

Explained below is an apparatus as well as a method intended to prevent the effects of oxidation and contamination on a sample in the atmosphere while polishing the sample efficiently in a vacuum.

### Means for Solving the Problem

Proposed below as one mode of solving the above problem is an apparatus as well as a method for subjecting a sample to ultrasonic polishing in a vacuum chamber. More specifically, there is proposed an apparatus furnished with a liquid bath filled with an ion liquid in a vacuum chamber, a supersonic vibration mechanism for propagating supersonic vibration in the ion liquid, and a sample transport mechanism, as well as a method for use with the apparatus.

### Effect of the Invention

The above-outlined mode permits polishing of an extensive area of the sample in a short period of time in a vacuum. When applied to a charged particle beam apparatus, the mode allows the processes of polishing, observation, and analysis to be repeated in a vacuum, thus eliminating the task of transporting samples in the atmosphere. This makes it possible to prevent oxidation and contamination of the sample while boosting the operability and throughput of the apparatus at the same time.

### BRIEF DESCRIPTION OF THE DRAWINGS

FIG. 1 is a schematic view showing a cross-section of an internal structure of a sample exchange chamber in a charged particle beam apparatus.

FIG. 2 is a schematic view showing an external appearance of the sample exchange chamber.

FIG. 3 is a photo showing an external appearance of a sample holder.

FIG. 4 is a schematic view showing how the tip of a sample rotation rod is attached to the bottom of the sample holder.

FIG. 5 is a set of schematic views showing an external appearance of a liquid bath, as well as where the liquid bath is attached to the bottom of the sample exchange chamber.

FIG. 6 is a chart showing the steps of polishing and observing a sample using an ion liquid in a vacuum.

FIG. 7 is a set of schematic views showing structures (positional relations between) of a sample chamber, a sample exchange chamber, and an ion milling gun of the charged particle beam apparatus.

FIG. 8 is a chart showing the steps of ion-milling and observing a sample.

FIG. 9 is a schematic block diagram of a scanning electron microscope.

FIG. 10 is a schematic block diagram of an ion milling apparatus.

FIG. 11 is an explanatory diagram showing a structure of the surroundings related to an ion gun.

FIG. 12 is a set of schematic views showing how the sample surface is polished differently depending on the supersonic vibration frequency.

FIG. 13 is a set of schematic views showing how a single sample and a plurality of samples are set up.

### MODES FOR CARRYING OUT THE INVENTION

Some embodiments of the present invention are explained below in detail with reference to the accompanying drawings. It should be noted that the embodiments to be discussed below are only examples and are not limitative of the present invention. For example, whereas the embodiments below involve having a sample exchange chamber furnished internally with a sample preparation apparatus that uses an ion liquid bath, the sample preparation chamber may be located instead in a sample chamber or some other space where a vacuum state is maintained.

### First Embodiment

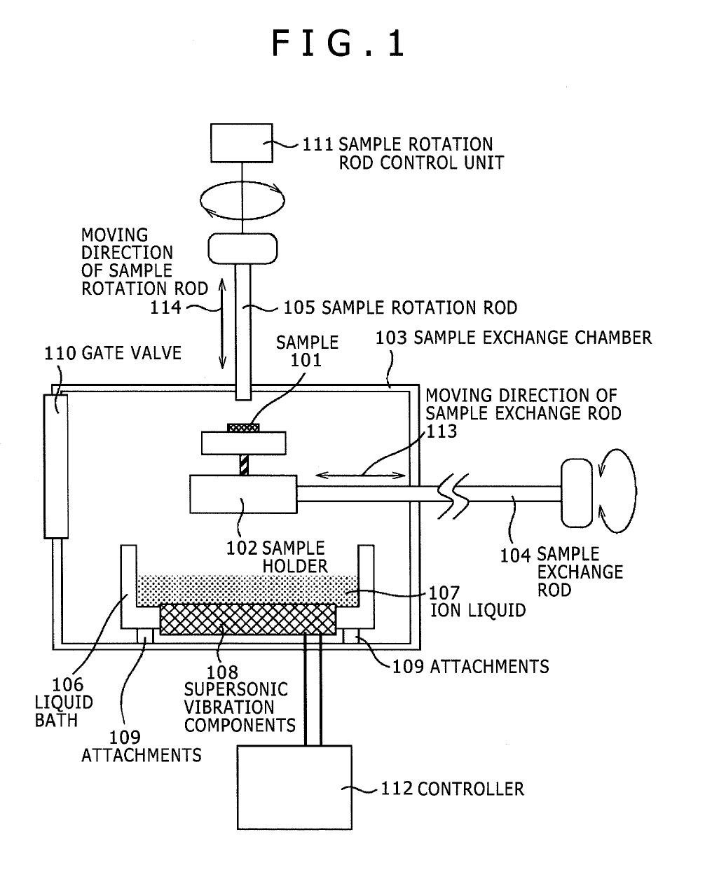

FIG. 1 is a schematic view showing a cross-section of an internal structure of a sample exchange chamber equipped with a sample preparation apparatus utilizing an ion liquid bath in a charged particle beam apparatus.

A sample 101 is fixed to a sample holder 102 as the object to be observed with the charged particle beam apparatus. The face to be observed on the sample 101 may be its surface or its cross-section. When the tip of a sample exchange rod 104 is attached to the fixed sample holder 102 and the sample exchange rod 104 is moved in its moving direction 113, the sample 101 can be dismounted, mounted, or moved integrally with the sample holder, 102 between a sample chamber and the sample exchange chamber. It is also possible for the sample exchange rod 104 to rotate on its axis. The tip of the sample exchange rod 104 is of a banana-shaped hair clip type or a two-pronged type and can be attached to the receiving side of the sample holder 102 (FIG. 3). As indicated by a sample rotation rod moving direction 114 in FIG. 1, a sample rotation rod 105 can be moved perpendicularly to the sample exchange rod moving direction 113. Also, a sample rotation rod control unit 111 allows the sample rotation rod 105 to rotate on its axis. Preparatory to inserting a sample into the sample chamber, the sample exchange chamber 103 is evacuated. Evacuation is accomplished by discharging the air from inside the sample exchange chamber using a vacuum pump or the like (not shown). A liquid bath 106 may be filled with an ion liquid 107. The liquid bath 106 also serves to collect excess ion liquid following polishing, as will be discussed later.

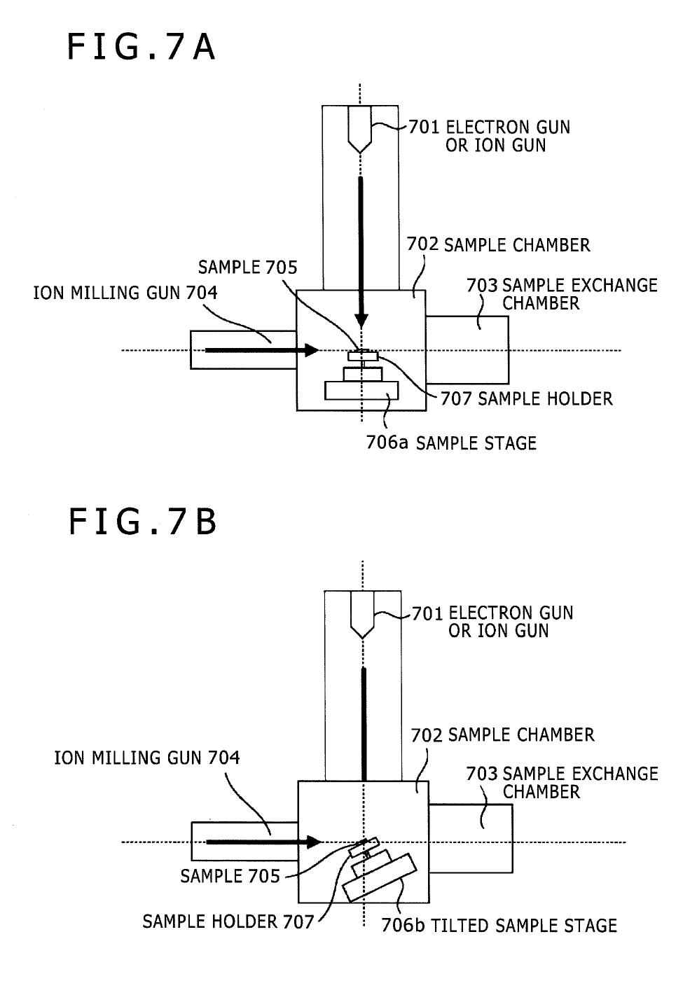

The substance to be contained in the liquid bath is not limited to the ion liquid as long as the liquid state of the substance in question is maintained in a vacuum. Still, the use of an ion liquid offers the advantage of allowing the type of ion to be selected depending on polishing and other conditions so that the liquid may have diverse properties in addition to those mentioned above. If there is provided a mechanism (not shown) to supply and discharge the ion liquid 107 to and from the liquid bath 106, the ion liquid can be changed (supplied or discharged) in a vacuum. Supersonic vibration components 108 under control of a controller 112 generate ultrasonic waves that propagate through the ion liquid 107 filling the liquid bath 106. The frequency at which to generate ultrasonic waves and the output of the generated waves may be varied under control of the controller 112 in keeping with the type of sample and the polishing conditions. Also, the supersonic vibration elements may be implemented in diverse shapes such as bars in addition to what is illustrated in FIG. 1. The supersonic vibration elements may also be attached either fixedly or removably to the liquid bath. Attachments 109 are structured to let the liquid bath 106 be attached and detached to and from the bottom of the sample exchange chamber. A gate valve 110 serves to block the sample chamber from the sample exchange chamber. The gate valve 110 is opened and closed only when the sample holder is transported between the sample chamber and the sample exchange chamber for the most part. The sample chamber and the sample exchange chamber are positioned as shown in FIG. 7.

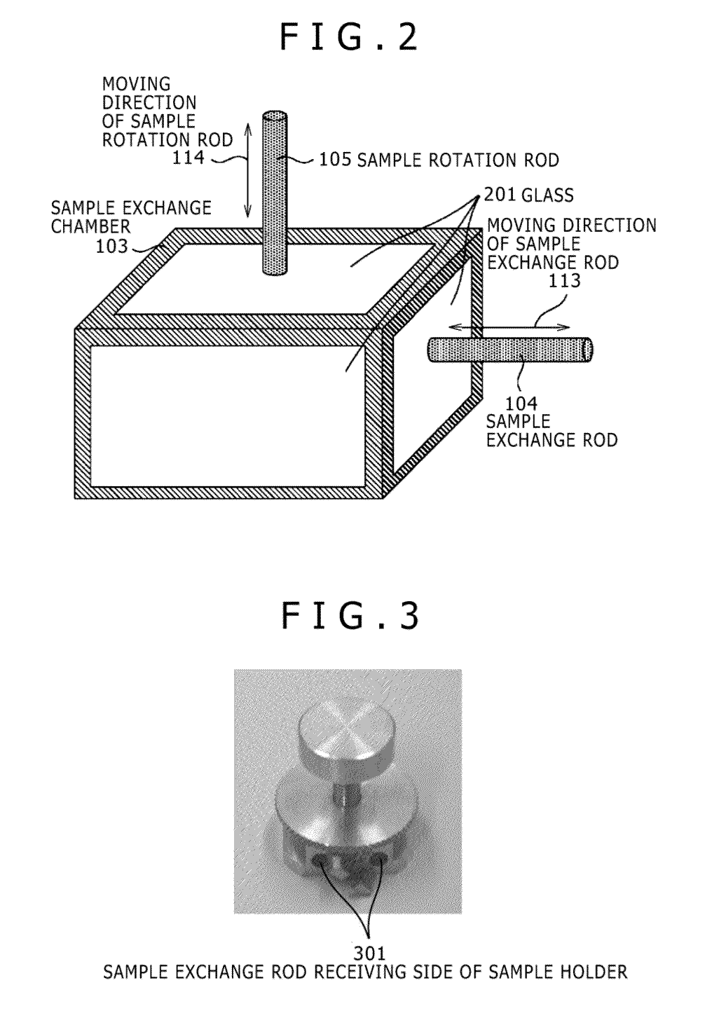

FIG. 2 is a schematic view showing an external appearance of the sample exchange chamber. One or all faces of the sample exchange chamber 103 may be made of a transparent material such as glass 201. This allows the polishing process on the sample in the vacuum state to be inspected visually or in some other appropriate manner as the sample is worked on with ease. As explained above with reference to FIG. 1, the sample exchange rod 104 and the sample rotation rod 105 can be moved and rotated, respectively.

FIG. 3 shows a typical structure of a sample exchange rod receiving side 301 of the sample holder. As illustrated, the sample exchange rod receiving side 301 of the sample holder has two holes into which the tip of the sample exchange rod 104 may be inserted.

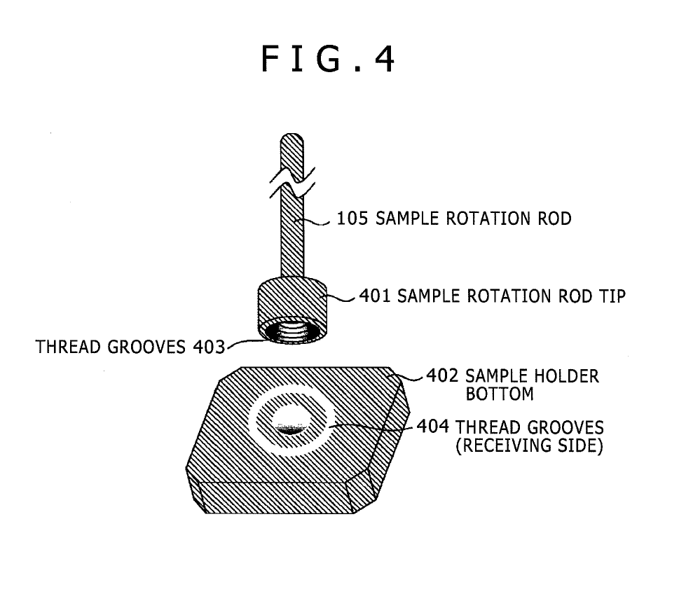

FIG. 4 is a schematic view showing how a sample rotation rod tip 401 is attached to a sample holder bottom 402. The sample rotation rod tip 401 is shaped as a hollow cylinder that has thread grooves 403 formed inside. The sample holder bottom (back side) 402 has thread grooves (receiving side) 404 formed inside to accommodate the sample rotation rod tip 401 therein. In this case, the direction in which the thread is tightened is the same as the direction in which the sample is actually rotated, so that the sample holder bottom 402 and the sample rotation rod tip 401 will not be detached from each other as the sample rotation rod 105 is being rotated on its axis.

When the sample holder bottom 402 and the sample rotation rod tip 401 are to be detached from each other, the sample rotation rod 105 may be rotated in the loosening direction with the sample exchange rod 104 still attached. This detaches the two parts from each other, without the sample holder getting rotated. Naturally, the sample holder will not drop.

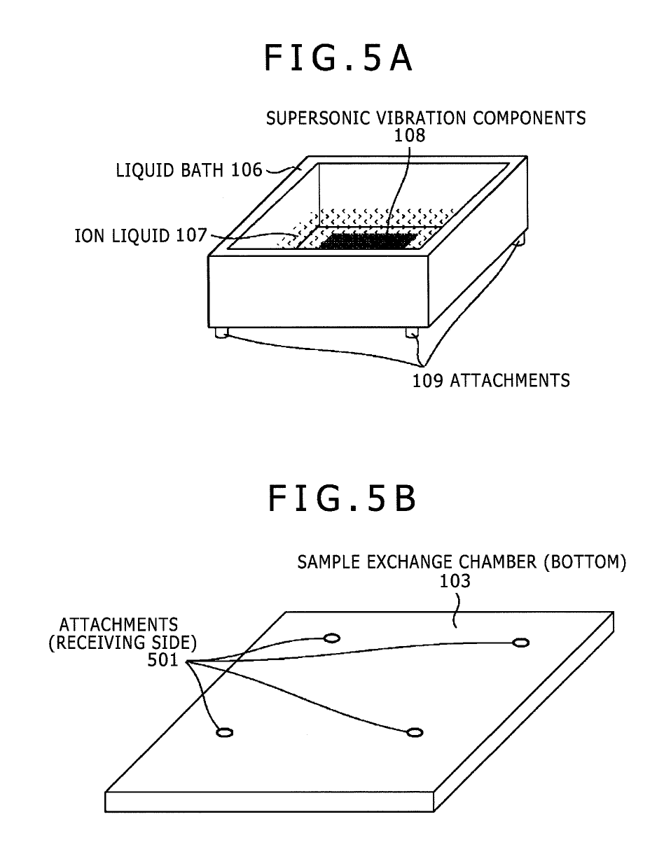

FIG. 5A is a schematic view of the liquid bath 106. As illustrated, the bottom of the liquid bath 106 has, on its predetermined positions, attachments 109 for attaching the liquid bath 106 fixedly to the bottom of the sample exchange chamber 103. FIG. 5B shows attachment receiving sides 501 furnished on the bottom of the sample exchange chamber 103. The attachment receiving sides 501 are positioned in a manner corresponding to the attachments 109 in FIG. 5A.

According to the first embodiment explained above, the sample preparation apparatus may be installed in a vacuum chamber with no special structures required.

### Second Embodiment

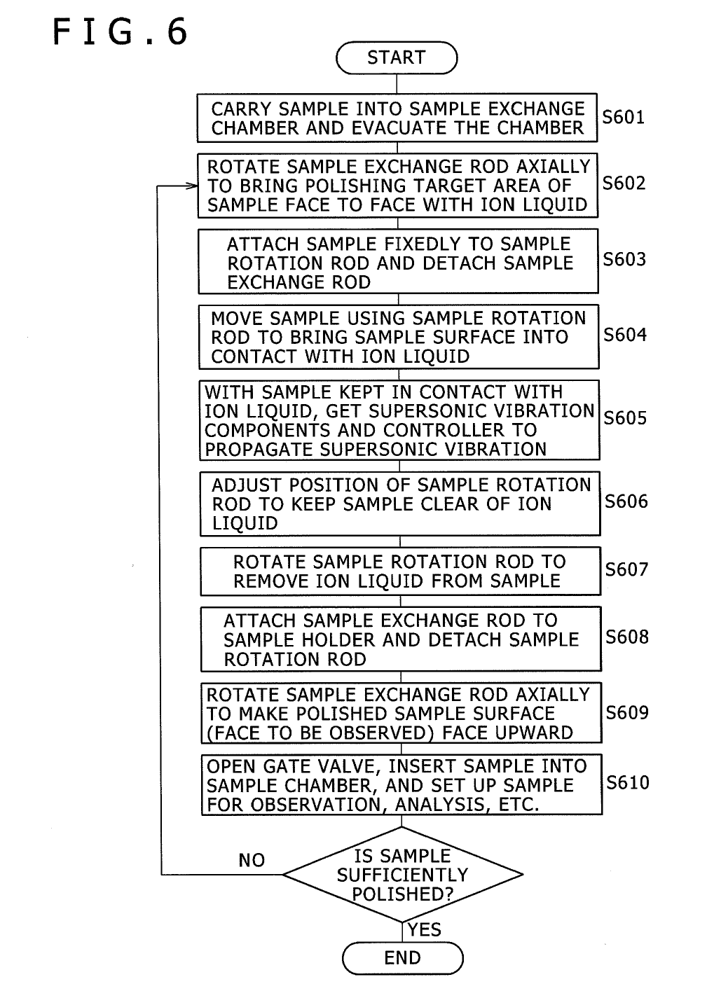

FIG. 6 is a flowchart showing the steps in which a sample is polished using an ion liquid in a vacuum on the above-described apparatus.

In the atmosphere, the sample 101 as the target to be polished is fixed using carbon paste, carbon tape (for tucking), nails, or some other mechanical fixtures, before being attached to the sample holder 102. The sample holder 102 mounted with the sample is fastened to the tip of the sample exchange rod 104. After the sample holder 102 together with the sample exchange rod 104 is carried into the sample exchange chamber 103, the sample exchange chamber 103 is evacuated (S601). Then the sample exchange rod 104 is axially rotated in such a manner that the sample-mounted surface of the sample holder comes face to face with the ion liquid in the liquid bath (S602). After the sample rotation rod 105 is attached fixedly to the sample holder 102, the sample exchange rod 104 is removed (S603).

The transport mechanism of the sample rotation rod 105 is used to bring the sample holder close to the ion liquid in such a manner that the sample surface area containing the location targeted for polishing comes into contact with the ion liquid (S604). At this point, the sample rotation rod 105 is fixed in a desired location so that the sample position will not vary. The method of bringing the sample into contact with the ion liquid is not limited to using the above-mentioned transport mechanism of the sample rotation rod. Some other suitable method permitting stable transportation of the sample may be adopted instead. The use of the sample rotation rod offers the advantage of there being no need for special structures and of removing the ion liquid using a rotation mechanism, to be discussed later. With the sample in contact with the ion liquid, the supersonic vibration components and the controller are caused to generate supersonic vibration that is propagated in the ion liquid for polishing purposes (S605).

Upon completion of polishing, the sample rotation rod 105 is unfastened. Using the transport mechanism of the sample rotation rod, the sample holder is positioned away from the liquid level, and is again fastened with the sample surface kept clear of the liquid level (S606). The rotation mechanism of the sample rotation rod 105 is used to flick the ion liquid off the sample by centrifugal force (S607). The rotation mechanism may be driven manually or automatically using a motor or the like. Since the sample holder is rotated in the same direction as the sample exchange rod 105, they will not be detached from each other. At this point, the ion liquid scattered by rotation adheres to the sidewalls of the liquid bath and is collected therein. The method of removing the ion liquid is not limited to what was described above. Many other methods may be used instead, such as blasting the sample with inert gas or bringing a magnet close to the sample. The use of the rotation mechanism of the sample rotation rod offers the advantage of there being no need for installing any new mechanism or of preventing a loss of vacuum due to blasting with gas.

Next, the sample rotation rod 105 is unfastened, the sample holder is moved away from the liquid level of the ion liquid, the sample exchange rod 104 is attached and fastened, and then the sample rotation rod 105 is removed (S608). The sample rotation rod 104 is rotated on its axis in such a manner that the face mounted with the polished sample comes face to face with a charged particle source of the sample chamber (S609). The gate valve between the sample chamber and the sample exchange chamber is opened, the sample holder is inserted into and set up in the sample chamber, and only the sample exchange rod is extracted from the sample chamber (S610). The gate valve between the sample chamber and the sample exchange chamber is then closed, and the sample is irradiated with a charged particle beam from the charged particle beam apparatus and observed. If it is determined after observation or during the course thereof that the sample was insufficiently polished and needs another (additional) polishing, suitable adjustments are made in such a manner that the state of step S605 is again reached so that supersonic vibration is again propagated in the ion liquid for another polishing.

In the above-described setup, the sample may be observed after polishing with the sample surface covered partially or totally with a very thin coat of ion liquid. In this case, if a sample with a low conductive property is under observation on the charged particle beam apparatus, the electrical charges accumulated on the sample surface are discharged via the ion liquid, which may provide advantageous effects such as charge-up reduction.

### Third Embodiment

FIG. 7A is a schematic view showing structures (positional relations between) of a sample chamber 702, sample exchange chamber 703, and an ion milling gun 704 of the charged particle beam apparatus, the ion milling gun 704 being installed to polish the sample.

An electron gun or an ion gun 701 of the charged particle beam apparatus emits a charged particle beam onto the sample. At this point, an observation is made based on the charged particles generated from the sample surface. The sample chamber 702 is evacuated to high vacuum for observation and for ion milling (flat milling) of the sample. The sample exchange chamber 703 is furnished internally with the structure explained above in connection with the first embodiment with reference to FIG. 1. The ion milling gun 704 has a mechanism for accelerating and focusing ions, thereby applying an ion beam to the sample to flick atoms off the sample surface for polishing. A sample 705 and a sample holder 707 are mounted on a sample stage 706a. The sample stage can be moved in the X- and Y-direction, R-direction (for rotation), T-direction (for tilt), and Z-direction (for elevation). Depending on the purpose, the sample stage is positioned verifiably and controlled using an operation screen and a control panel (not shown) of the charged particle beam apparatus so as to apply the ion beam to an optimum irradiation position. FIG. 7B shows a typically tilted sample stage 706b.

Where ion milling is performed using the ion milling gun as described above, the sample area that can be polished in one pass is limited; this method is not suitable for polishing an extensive area of the sample. Thus several methods may be combined as needed depending on conditions in order to polish the sample in a short period of time. For example, the sample preparation apparatus explained above in connection with the first and the second embodiments may be used roughly to polish a wide area of the sample (coarse polishing), and then the ion milling method may be employed for fine polishing as when the roughly polished sample is smoothed to attain a desired state for observation and analysis (final polishing).

### Fourth Embodiment

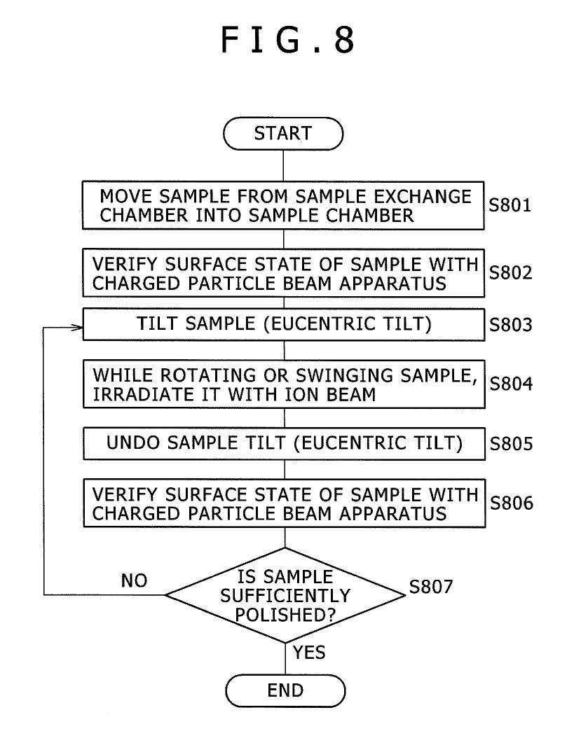

FIG. 8 is a chart showing the steps in which a sample is ion-milled and observed.

After the processing discussed above in conjunction with the first and the second embodiments, the sample is moved from the sample exchange chamber into the sample chamber (S801). After the surface state of the sample is verified using the charged particle beam apparatus (S802), the sample is tilted by the sample stage (S803). At this point, a eucentric tilting function of the charged particle beam apparatus may be used to tilt the sample in a manner keeping the visual field of observation at the center of the screen. The eucentric tilting function allows the visual field of observation to move in reference to the irradiation position of the charged particle beam on the sample during rotation or tilting, for example, so that the visual field of observation remains fixed even as the tilting angle is varied. With the sample stage adjusted to rotate or swing the sample continuously, the ion gun emits an ion beam to the sample (S804). After the tilted sample is returned to its original position (S805), the surface state of the sample is observed using the charged particle beam apparatus (S806). Alternatively, with the tilted sample left in its position, the surface state of the sample may be observed using the charged particle beam apparatus. It is determined by observation whether the sample has been sufficiently polished (S807). If the sample is determined to be sufficiently polished, work is terminated; if the sample is determined to be insufficiently polished, step S803 is reached again and the subsequent flow of steps is repeated. If some ion liquid is left on the sample surface subsequent to polishing with the first embodiment, step S803 may be reached as needed for another ion milling over a short period of time, whereby the remaining ion liquid may be removed. At this point, the accuracy of positioning for polishing can be enhanced if the ion milling position is determined while the sample is observed even as the stage of the charged particle beam apparatus is being moved.

Also, if it becomes necessary to again perform rough polishing of the sample following final polishing or observation, the sample may be moved from the sample chamber into the example exchange chamber, and step S602 and subsequent steps in FIG. 6 may be repeated to again polish the sample with supersonic vibration. In this manner, the entire process from coarse polishing to fine polishing to observation can be performed within one charged particle beam apparatus, and individual steps may be repeated as needed depending on the purpose. Because there is no need to expose the sample in the atmosphere throughout the entire process, the sample and the ion liquid adhering thereto are not contaminated with impurities, which shortens the time it takes to accomplish the task.

Furthermore, if a stage history is registered with the charged particle beam apparatus, it is easy for the sample to be moved between the position for polishing and the position for observation.

### Fifth Embodiment

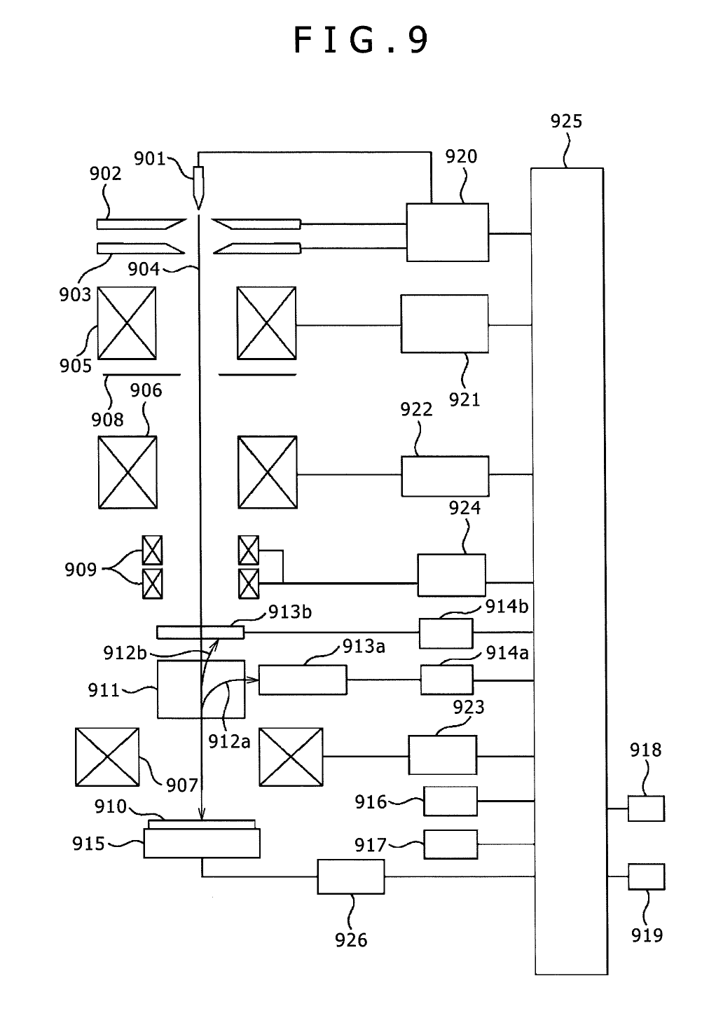

FIG. 9 is a schematic block diagram of a scanning electron microscope (SEM) as one type of charged particle beam apparatus for observing the sample polished as discussed above. The basic components are structured substantially the same as those in FIG. 7.

Between an electron source (cathode) 901 and a first anode 902, a voltage is applied by a high-voltage control power supply (920) under control of a microprocessor (CPU) 925. A primary electron beam 904 is extracted from the electron source (cathode) 901 with a predetermined emission current. Because an acceleration voltage is applied between the electron source (cathode) 901 and a second anode 903 by the high-voltage control power supply 920 under control of the microprocessor (CPU) 925, the primary electron beam 904 emitted from the electron source (cathode) 901 is accelerated and advanced to a downstream lens system.

The primary electron beam 904 is focused by a first focusing lens 905 (beam focusing means) under control of a first focusing lens control power supply 921. Unnecessary regions of the primary electron beam 904 are removed by a diaphragm plate 908. The primary electron beam 904 is then focused on the sample 910 as a minute spot by a second focusing lens 906 (beam focusing means) under control of a second focusing lens control power supply 922 and by an object lens 907 controlled by an object lens control power supply 923. The object lens 907 can take various forms such as an in-lens system, an out-lens system, or a snorkel system (semi-in-lens system).

The top of the sample 910 is scanned two-dimensionally with the primary electron beam 904 using a scanning coil 909. The signal of the scanning coil 909 is controlled by a scanning coil control power supply 924 according to observation magnification. Under irradiation of the primary electron beam, a low-energy secondary signal 912a and a high-energy secondary signal 912b such as secondary electrons generated from the sample 910 are advanced to an upper part of the object lens 907, before being separated according to energy difference by an orthogonal electromagnetic field (EXB) generation device 911 for secondary signal separation, and forward to and detected by a low-energy secondary signal detector 913a and a high-energy secondary signal detector 913b, respectively. There may be provided a plurality of detectors as described above, or there may be a single detector. The signal of the low-energy secondary signal detector 913a and that of the high-energy secondary signal detector 913b are fed through a low-energy secondary signal amplifier 914a and a high-energy secondary signal amplifier 914b, respectively, before being stored into a display image memory 916 as image signals. Image information stored in the display image memory 916 is displayed as needed on an image display device 917.

Through an input device 918, it is possible to designate image import conditions (scan rate, acceleration voltage, etc.), move a sample stage 915 by means of a sample stage control power supply 926, and designate the output and storage of images. The image data stored in an image memory 919 can be exported from the SEM.

### Sixth Embodiment

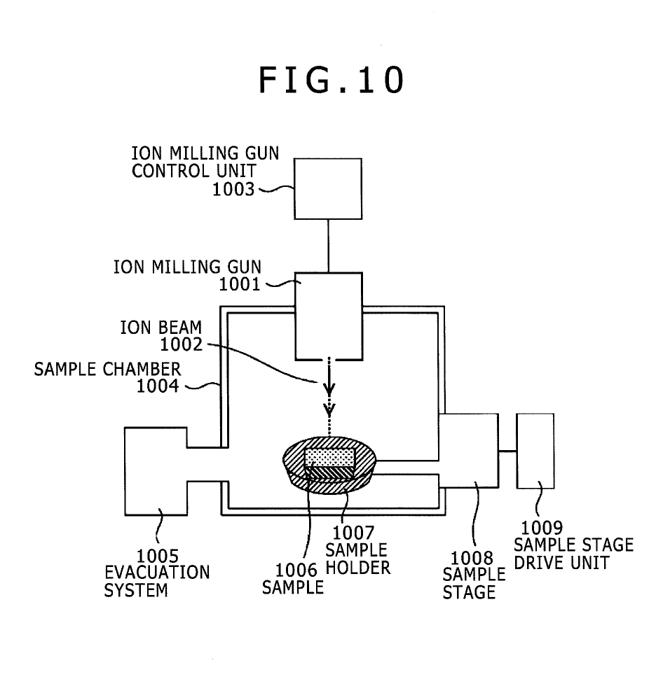

FIG. 10 is an explanatory diagram showing a structure of an ion milling machine according to the present invention. The diagram illustrates one type of machine for performing fine polishing (final polishing) of the sample through ion milling as indicated in FIG. 8.

An ion milling gun 1001 constitutes an irradiation system that irradiates a sample with an ion beam 1002. An ion milling gun control unit 1003 controls the irradiation and current density of the ion beam. An evacuation system 1005 controls a sample chamber 1004 of the charged particle beam apparatus at atmospheric pressure or in a vacuum, and can maintain that state. A sample 1006 is held on a sample holder 1007. The sample holder 1007 is in turn held on a sample stage 1008. Also, the sample holder 1007 can be extracted from the sample chamber 10004 of the charged particle beam apparatus into a sample exchange chamber. The sample stage 1008 is equipped with components for tilting the sample 1006 at a desired angle relative to the optical axis of the ion beam 1002. A sample stage drive unit 1009 can rotate the sample stage 1008 or swing it crosswise at varying speeds.

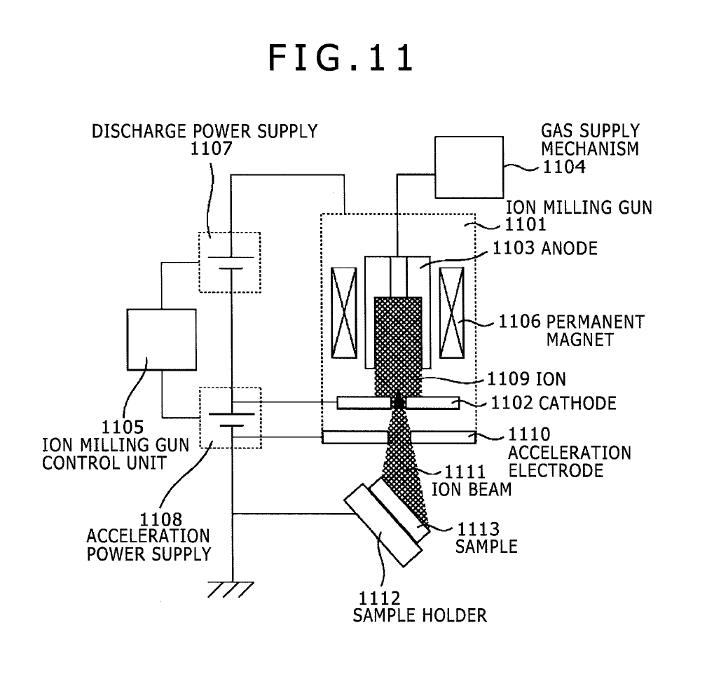

FIG. 11 is an explanatory diagram showing a structure of the surroundings related to an ion milling gun 1101. The ion milling gun 1101 corresponds to the ion milling gun 704 in FIG. 7 and the ion milling gun 1001 in FIG. 10.

The ion milling gun 1101 is made up of a cathode 1102 paired with an anode 1103 facing a depressurized vacuum chamber, a gas supply mechanism 1104, an acceleration electrode 1110, and a permanent magnet 1106. An ion milling gun control unit 1105 is connected to a discharge power supply 1107 and an acceleration power supply 1108 which control discharge voltage and acceleration voltage, respectively. The gas supply mechanism 1104 is equipped with components for adjusting the flow rate of the gas to be ionized and supplied into the ion gun. Although the gas used here for purpose of explanation is argon gas, this is only an example and is not limitative of the invention. The cathode 1102 has a hole serving as an orifice that keeps at an appropriate partial pressure the argon gas introduced from the gas supply mechanism 1104. With the suitable gas partial pressure maintained, a discharge voltage of about 0 to 4 kV is applied between the cathode 1102 and the anode 1103. This causes a sustained discharge phenomenon called glow discharge in a low-pressure atmosphere, thereby generating ions 1109. At this point, the permanent magnet 1106 causes the electrons generated by discharge to rotate and prolong their paths so as to improve discharge efficiency. An acceleration voltage of about 0 to 10 kV is applied between the cathode 1102 and the acceleration electrode 1110 to accelerate the ions 1109. This causes an ion beam 1111 to be emitted onto the surface of a sample 1113 held by a sample holder 1112.

### Seventh Embodiment

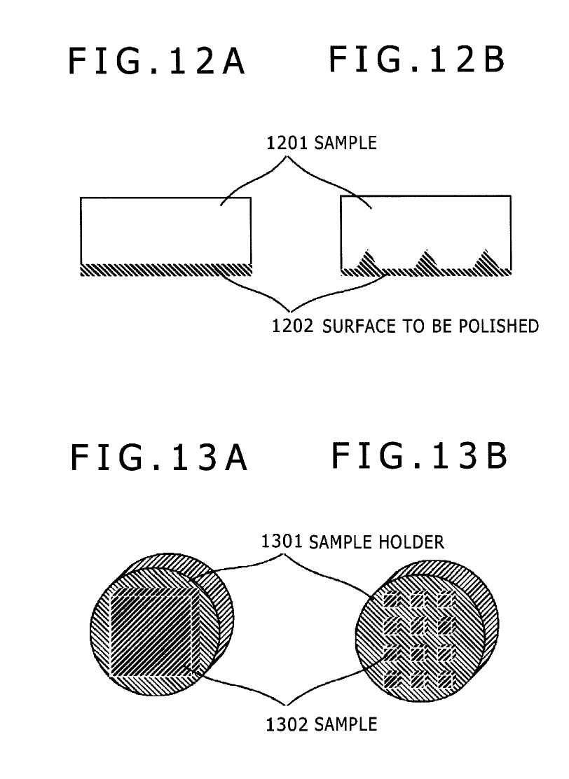

FIG. 12 is a set of schematic views showing how the sample surface is polished differently depending on the supersonic vibration frequency.

The frequency and the output of the controller 112 controlling the supersonic vibration components 108 of the first embodiment are variable. The frequency is derived from a power supply of tens of kHz to 1 MHz. That is because the entire surface of the sample is to be polished flat as shown in FIG. 12A. Excessively low frequencies can lead to higher polishing speeds resulting in a damaged sample surface; a smooth surface may not be obtained in such cases. Where the frequency is set under these conditions, it is possible to secure a newly polished, extensive area so that not limited locations but numerous locations over the wide area of the sample may be submitted to averaged evaluation. Also, when the frequency of supersonic vibration is made lower than the settings for polishing in FIG. 12A, only limited locations of the sample can be polished (in conical shape) as illustrated in FIG. 12B. This permits polishing of the sample with cross-sections of different depths, which makes it possible to observe individual layers and interfaces of a multilayer sample.

FIG. 13A is a schematic view showing a single sample being set up and FIG. 13B is a schematic view indicating a plurality of samples being set up. When multiple samples are set up with their tops made flush with one another, they can be polished at the same time.

Compared with focused ion beam (FIB) polishing and broad ion beam polishing (ion milling), ultrasonic polishing according to the present invention is not subject to the constraints on the area to be polished so that an extensive area of the sample can be polished.

### Eighth Embodiment

The electrodes of the lithium ion battery contain lithium (Li) and lithium compounds which, upon reaction with the components of the atmosphere (oxygen, nitrogen, moisture, etc.), change instantaneously in form and structure and proceed with chemical reactions. If these substances are handled by the embodiments of the sample preparation apparatus according to the invention, the substances are protected against such reactions during polishing, transport and observation, because all the processes of polishing and observation can be performed in a vacuum; a newly polished surface of the sample can be observed as polished. In addition to lithium and lithium compounds, such substances as metallic magnesium prone to oxidation, and sample contamination can benefit from the same effects.

### Ninth Embodiment

If the structure, form, and thickness (depth) of multilayer samples typified by semiconductor devices are known in advance, the sample may be polished (in rough and fine polishing) by the above-described embodiments and observed on the charged particle beam apparatus repeatedly until a desired state of the sample is attained so that the target internal structures of the sample may be observed and analyzed. In this case, the area to be polished and the depth to be reached on the sample can be readily adjusted by varying the frequency of supersonic vibration as explained above in conjunction with the seventh embodiment. If the target structure to be observed is located in an internal region far from the sample surface and if the target structure is infinitesimal in size, the accuracy of the target structure in the depth direction is enhanced by repeating ultrasonic polishing and observation using the charged particle beam apparatus of the third embodiment shown in FIG. 7 provided the apparatus is an FIB.

This improves the accuracy of positioning (in X- and Y-directions) for the next round of polishing by FIB and thereby shortens polishing time. Furthermore, the work involved is simple and requires no special skills.

Even samples prone to rapid reaction or contamination in the atmosphere can be polished as desired under conditions where the atmosphere is blocked. With the newly polished surface of the sample protected against exposure to the atmosphere, the polished sample can be observed as polished.

### DESCRIPTION OF REFERENCE CHARACTERS

101, 910, 1006, 1113, 1201, 1302 Sample
102, 1007, 1112, 1301 Sample holder
103, 703 Sample exchange chamber
104 Sample exchange rod
105 Sample rotation rod
106 Liquid bath
107 Ion liquid
108 Supersonic vibration components
109 Attachments
110 Gate valve
111 Sample rotation rod control unit
112 Controller
113 Moving direction of sample exchange rod
114 Moving direction of sample rotation rod
201 Glass
301 Sample exchange rod receiving side of sample holder
401 Sample rotation rod tip
402 Sample holder bottom
403 Thread grooves
404 Thread grooves (receiving side)
501 Attachments (receiving side)
701 Electron gun or ion gun
702, 1004 Sample chamber
704, 1001, 1101 Ion milling gun
705 Sample and sample holder
706a, 915, 1008 Sample stage
706b Tilted sample stage
901 Electron source (cathode)
902 First anode
903 Second anode
904 Primary electron beam
905 First focusing lens
906 Second focusing lens
   907 Object lens
908 Diaphragm plate
909 Scanning coil
911 Orthogonal electromagnetic field (EXE) generation device for secondary signal separation
912a Low-energy secondary signal
912b High-energy secondary signal
913a Low-energy secondary signal detector
913b High-energy secondary signal detector
914a Low-energy secondary signal amplifier
914b High-energy secondary signal amplifier
916 Display image memory
917 Image display device
918 Input device
919 Image memory
920 High-voltage control power supply
921 First focusing lens control power supply
922 Second focusing lens control power supply
923 Object lens control power supply
924 Scanning coil control power supply
925 Microprocessor (CPU)
926 Sample stage control power supply
1002, 1111 Ion beam
1003, 1105 Ion milling gun control unit
1005 Evacuation system
1009 Sample stage drive unit
1102 Cathode
1103 Anode
1104 Gas supply mechanism
1106 Permanent magnet
1107 Discharge power supply
1108 Acceleration power supply
1109 Ions
1110 Acceleration electrode
1202 Face to be polished

1. A charged particle beam apparatus comprising:
an electron optics system which irradiates a sample with charged particles;
a detection system which detects charged particles released from said sample; and
a vacuum chamber, wherein:
said vacuum chamber is furnished with:
a liquid bath which holds a liquid, and
a supersonic vibration mechanism which generates supersonic vibration; and
said supersonic vibration mechanism propagates supersonic vibration in the liquid inside said liquid bath.

2. A charged particle beam apparatus according to claim 1, wherein said liquid is an ion liquid.

3. A charged particle beam apparatus according to claim 1, wherein:
said vacuum chamber is furnished with a moving mechanism which moves said sample; and
said moving mechanism is interposed between said electron optics system and said liquid bath.

4. A charged particle beam apparatus according to claim 3, wherein:
said vacuum chamber is furnished with a valve which is positioned on a moving orbit of said moving mechanism and which can be opened and closed to block the inside of said vacuum chamber into spaces; and
at least one of the blocked spaces is furnished with an evacuation mechanism.

5. A charged particle beam apparatus according to claim 3, wherein said moving mechanism is furnished with a rotation mechanism which rotates said sample.

6. A charged particle beam apparatus according to claim 1, wherein:
said vacuum chamber is furnished with a liquid removal mechanism which removes said liquid; and
said liquid removal mechanism is interposed between said electron optics system and said liquid bath.

7. A charged particle beam apparatus according to claim 6, wherein said liquid removal mechanism is an inert gas supply mechanism.

8. A charged particle beam apparatus according to claim 1, wherein:
said vacuum chamber is furnished with a control mechanism which controls said supersonic vibration; and
said control mechanism controls said supersonic vibration mechanism to vary said supersonic vibration in frequency.

9. A charged particle beam apparatus according to claim 1, wherein:
said vacuum chamber is furnished with a milling mechanism which irradiates a surface of said sample with ions for milling purposes; and
said milling mechanism is interposed between said electron optics system and said liquid bath.

10. A charged particle beam apparatus according to claim 1, wherein said vacuum chamber is furnished with a liquid supply mechanism which supplies said liquid between said vacuum and the outside.

11. A sample preparation apparatus comprising a vacuum chamber, wherein:
said vacuum chamber is furnished with:
a liquid bath which holds a liquid, and
a supersonic vibration mechanism which generates supersonic vibration;
said supersonic vibration mechanism propagates supersonic vibration in the liquid inside said liquid bath; and
wherein said liquid is an ion liquid.

12. (canceled)

13. A sample preparation apparatus according to claim 11, wherein at least one of the wall surfaces constituting said vacuum chamber includes a material having transparency.

14. A sample preparation apparatus according to claim 13, wherein said material includes a glassy substance.

15. A sample preparation method for preparing a sample in a vacuum, said method comprising:
a first step of bringing an ion liquid into contact with that area of the sample which includes a location targeted for polishing; and
a second step of propagating supersonic vibration in the ion liquid in contact with said area of said sample.

16. A sample preparation method according to claim 15, wherein said second step is followed by removal of the ion liquid adhering to said sample.

17. A sample observation method for irradiating a sample with a charged particle beam and observing said sample based on an image obtained by detecting charged particles released from said sample, said sample observation method comprising:
a first step of bringing an ion liquid in a vacuum into contact with that area of said sample which includes a location targeted for polishing;
a second step of propagating supersonic vibration in the ion liquid, and
a step of observing said sample subsequent to said second step.

18. A sample observation method according to claim 17, wherein said second step is followed by removal of the ion liquid adhering to said sample.

19. A sample observation method according to claim 17, wherein said second step is followed by irradiation of said sample with an ion beam for ion-milling said sample.
